(19) United States
(12) Patent Application Publication
(10) Pub. No.: US 2007/0045655 A1
(43) Pub. Date: Mar. 1, 2007

(54) Nitride semiconductor light emitting device

(75) Inventors: Keun Man Song, Seoul (KR); Dong Yul Lee, Kyungki-do (KR); Sun Woon Kim, Seoul (KR); Je Won Kim, Kyungki-do (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/508,145

(22) Filed: Aug. 23, 2006

(30) Foreign Application Priority Data
Aug. 25, 2005 (KR) 10-2005-0078419

(51) Int. Cl. H01L 29/00

(52) U.S. Cl. 257/104

(57) ABSTRACT

The invention relates to a high-output, high-efficiency nitride semiconductor light emitting device with low operating voltage and high resistance to electrostatic discharge. The nitride semiconductor light emitting device includes an n-contact layer formed on a substrate and a current spreading layer formed on the n-contact layer. The nitride semiconductor light emitting device also includes an active layer formed on the current spreading layer and a p-clad layer formed on the active layer. The current spreading layer comprises at least three multiple layers composed of at least one first nitride semiconductor layer made of InₓGa₍₁₋ₓ₎N, where 0<x<1 and at least one second nitride semiconductor layer made of In_{y}Ga_{(1-y)}N, where 0≦y<1 and y<x, the first and second nitride semiconductor layers formed alternately. The multiple nitride semiconductor layers comprise some layers doped with n-type dopant and other layers which are undoped.

### CLAIM OF PRIORITY

This application claims the benefit of Korean Patent Application No. 2005-78419 filed on Aug. 25, 2005, in the Korean Intellectual Property Office, the disclosure of which is incorporated herein by reference.

### BACKGROUND OF THE INVENTION

1. Field of the Invention

The present invention relates to a nitride semiconductor light emitting device, and more particularly, to a nitride semiconductor light emitting device which achieves uniform light emission to obtain high light emission efficiency and high resistance to electrostatic discharge (ESD)

2. Description of the Related Art

Recently, group III nitride semiconductors (or simply nitride semiconductors) have been popularized as a core material for light emitting devices such as a Light Emitting Diodes (LEDs) or Laser Diodes (LDs) due to their superior physical and chemical properties. The LEDs or LDs made of the nitride semiconductor material are extensively adopted in light emitting devices for obtaining blue or green wavelength of light. Such nitride semiconductor light emitting devices are applied to light sources of various products such as electronic display boards, lighting apparatuses, and the like. The nitride semiconductor is typically made of a GaN-based material having a composition of InₓAl_{y}Ga_{(1-x-y)}N, where 0≦x≦1, 0≦y≦1 and 0≦x+y≦1. Increasingly adopted as components for various electronic products, it has become important that the nitride semiconductor light emitting devices have good light emission performance as well as high reliability.

As shown in FIG. 1, a general nitride semiconductor LED device 10 basically includes a buffer layer 12 made of GaN, an n-type GaN-based clad layer 13, an active layer 14 of a InGaN/GaN single quantum well structure or multiple quantum well structure and a p-type GaN-based clad layer 15 formed in their order on a substrate 11 of sapphire which is an insulation substrate. As shown, an n-electrode 18 is formed on an upper surface of the n-type GaN-based clad layer 13 exposed by mesa-etching. And a transparent electrode layer 16 made of Indium Tin Oxide (ITO) and a p-electrode 17 are successively formed on the p-type GaN clad layer 15. Japanese Laid Open Patent Publication Hei10-135514 discloses a light emitting device having an active layer which includes a multiple quantum well structure with a barrier layer of undoped GaN and a well layer of undoped InGaN, and which also includes clad layers with greater band gap than that of the barrier layer in order to improve efficiency and intensity of light emission.

However, the nitride semiconductor light emitting devices used for the light source for illumination such as outdoor displays need to have improved light output and light emission efficiency. In particular, a nitride semiconductor LED or LD needs to have lowered threshold voltage or operating voltage V_{f} to reduce heat generation thereof while improving reliability and lifetime thereof. In addition, typically having low resistance to electrostatic discharge (ESD), the nitride semiconductor light emitting device needs to improve its ESD characteristics. The LED/LD can easily be damaged by ESD which is generated in people or objects. Particularly, current can be concentrated between the p-electrode and the n-electrode, causing non-uniform light emission and thereby resulting in low light emission efficiency and weak resistance to ESD.

Various researches have been conducted on ways to prevent damage to the nitride semiconductor light emitting device by ESD while increasing the intensity of light emission of the device. For example, U.S. Pat. No. 6,593,597 discloses technology in which an LED device and a short key diode are integrated on a single substrate and connected in parallel to protect the light emitting device from ESD. In addition, there have been suggested methods for connecting a zener diode and an LED to improve resistance to ESD. However, such conventional methods fail to suggest ways to increase efficiency and intensity of light emission, thus causing inconvenience of purchasing additional zener diode or forming short key junction.

### SUMMARY OF THE INVENTION

The present invention has been made to solve the foregoing problems of the prior art and therefore an object of certain embodiments of the present invention is to provide a nitride semiconductor light emitting device having an improved light emission efficiency and low operating voltage.

Another object of certain embodiments of the invention is to provide a nitride semiconductor light emitting device which can achieve high resistance to ESD without having an additional device.

According to an aspect of the invention for realizing the object, there is provided a nitride semiconductor light emitting device including: an n-contact layer formed on a substrate; a current spreading layer formed on the n-contact layer; an active layer formed on the current spreading layer; and a p-clad layer formed on the active layer. The current spreading layer comprises at least three multiple layers composed of at least one first nitride semiconductor layer made of InₓGa₍₁₋ₓ₎N, where 0<x<1 and at least one second nitride semiconductor layer made of In_{y}Ga_{(1-y)}N, where 0≦y<1 and y<x. The first and second nitride semiconductor layers are formed alternately. The multiple nitride semiconductor layers may comprise some successive layers doped with n-type dopant and other layers which are undoped.

According to an embodiment of the present invention, the multiple nitride semiconductor layers may comprise some successive layers doped with n-type dopant and other successive layers which are undoped.

According to an embodiment of the invention, the some successive layers of the multiple nitride semiconductor layers doped with n-type dopant have the same doping concentration. Alternatively, some of the nitride semiconductor layers doped with n-type dopant have the same doping concentration and other nitride semiconductor layers doped with n-type dopant have varying doping concentrations.

According to an embodiment of the invention, the first nitride semiconductor layer is made of InGaN and the second nitride semiconductor layer is made of GaN. In this case, the first nitride semiconductor layer is made of InₓGa₍₁₋ₓ₎N, where 0.05<x<3, and the second nitride semiconductor is made of GaN.

According to an embodiment of the invention, the first nitride semiconductor layers may have the same composition. Alternatively, the first nitride semiconductor layers may have compositions varying according to a distance in a thickness direction. For example, the first nitride semiconductor layers may have In contents varying greater or smaller toward the active layer. In addition, some first nitride semiconductor layers may have the same composition and other first nitride semiconductor layers have varying compositions.

According to an embodiment of the invention, the multiple layers may have the same thickness. Alternatively, the multiple layers may have varying thicknesses. For example, the first nitride semiconductor layers or the second nitride semiconductor layers may have thicknesses varying greater or smaller toward the active layer. In addition, some of the first nitride semiconductor layers may have the same thickness and some of them have varying thicknesses.

Preferably, each of the first nitride semiconductor layer and the second nitride semiconductor layer may have a thickness of up to 5 nm. With the thickness of each of the first and second nitride semiconductor layers having a thickness of up to 5 nm, the current spreading layer form multiple layers of a super lattice structure having good crystallinity.

According to an embodiment of the invention, the first nitride semiconductor layers may have varying compositions and thicknesses. In addition, some first nitride semiconductor layers may have the same composition and thickness and other first nitride semiconductor layers may have varying compositions and thicknesses.

According to an embodiment of the invention, the nitride semiconductor light emitting device may further include a buffer layer having multiple layers of nitride semiconductor/SiC between the substrate and the n-contact layer. In this case, the buffer layer includes a SiC layer formed on the substrate and an InGaN layer formed on the SiC layer. Further, the nitride semiconductor light emitting device may further include an undoped GaN layer formed between the substrate and the buffer layer.

According to an embodiment of the invention, the nitride semiconductor light emitting device may further include a carbon C modulated doped layer formed between the n-contact layer and the current spreading layer. The C modulated doping layer has a carbon doping concentration which is modulated according to a distance in a thickness direction. This C modulated doping layer allows further enhanced resistance to electrostatic discharge.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional diagram illustrating a conventional nitride semiconductor light emitting device;

FIG. 2 is a sectional diagram illustrating a nitride semiconductor light emitting device according to an embodiment of the present invention;

FIG. 3 is a partial sectional diagram illustrating a current spreading layer according to an embodiment of the present invention;

FIGS. 4 to 7 are diagrams illustrating conduction band edges of the current spreading layers to explain the compositions of the current spreading layers according to other embodiments of the present invention;

FIGS. 8 and 9 are diagrams illustrating conduction band edges of the current spreading layers to show varying thicknesses of nitride semiconductor layers constituting the current spreading layers;

FIG. 10 is a sectional view illustrating a nitride semiconductor light emitting device according to another embodiment of the present invention;

FIG. 11 is a sectional view illustrating a part of a nitride semiconductor light emitting device according to yet another embodiment of the present invention; and

FIG. 12 is a graph showing the profile of carbon doping concentration of a carbon modulated doping layer according to the present invention.

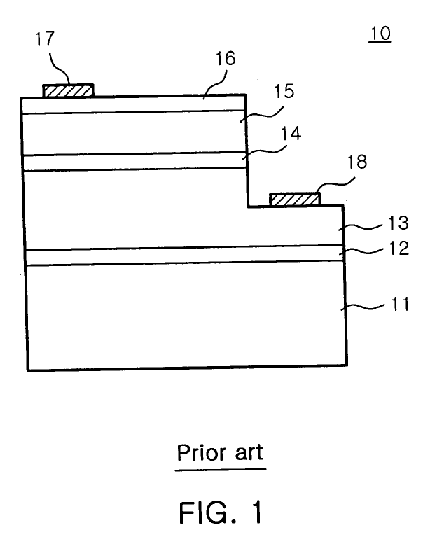

### DETAILED DESCRIPTION OF THE PREFERRED EMBODIMENT

Preferred embodiments of the present invention will now be described in detail with reference to the accompanying drawings. The invention may however be embodied in many different forms and should not be construed as limited to the embodiments set forth herein. Rather, these embodiments are provided so that this disclosure will be thorough and complete, and will fully convey the scope of the invention to those skilled in the art. In the drawings, the thickness, shapes and dimensions may be exaggerated for clarity and the same reference numerals are used throughout to designate the same or similar components.

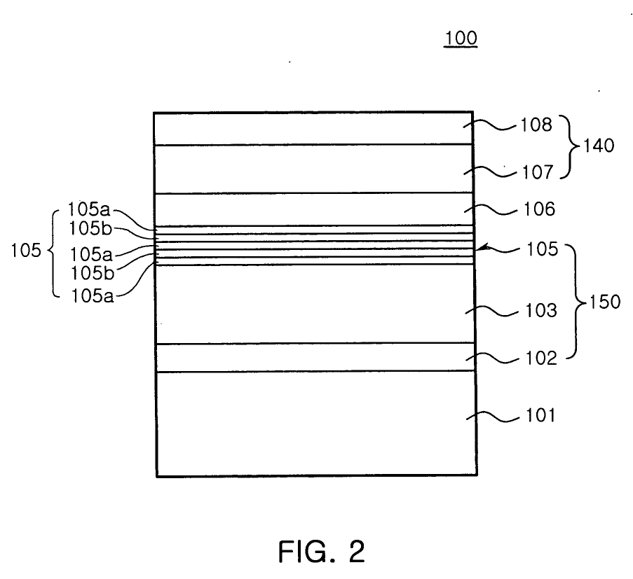

FIG. 2 is a sectional view illustrating a nitride semiconductor light emitting device 100 according to an embodiment of the present invention. Referring to FIG. 2, the nitride semiconductor light emitting device 100 includes an undoped GaN layer 102, an n-contact layer 103, a current spreading layer 105, an active layer 106, a p-clad layer 107 and a p-contact layer 108 formed in their order on a substrate 101 of sapphire. This embodiment is exemplified by a sapphire substrate, but alternatively, a semiconductor substrate for example a SiC substrate, a Si substrate, a ZnO substrate, a GaAs substrate, and a GaN substrate or an insulation substrate such as a spinel MgAl₂O₄ can be used.

It is preferable that the n-contact layer 103 adopts Al_{z}GaN, where 0<z<0.3, and has a thickness ranging from 0.5 to 5 μm. In addition, it is preferable that its n-type dopant concentration (doping concentration) ranges from 3×10¹⁸ to 5×10²¹ cm⁻³. As the doping concentration of the n-contact layer 103 increases, the operating voltage V_{f} is decreased within a range that does not degrade crystallinity. However, if the doping concentration of the n-contact layer 103 is excessively high, the crystallinity degrades, and thus it is preferable that the doping concentration of the n-contact layer 103 does not exceed 5×10²¹ cm⁻³.

The undoped GaN layer 102, the n-contact layer 103 and the current spreading layer 105 constitute an n-side region 150 of the light emitting device 100. A part of the current spreading layer 105 and the n-contact layer 103 are made of n-type nitride semiconductor doped with n-type dopant. For the n-type dopant, for example, Si, Ge and Sn can be used, among which Si is preferable.

In the meantime, the p-clad layer 107 and the p-contact layer 108 constitute a p-side region 140 and are made of p-type nitride semiconductor doped with p-type dopant. For the p-type dopant, for example, Mg, Zn and Be can be used, among which Mg is preferable. The active layer 106 sandwiched between the n-side region 150 and the p-side region 140 may for example have a multiple quantum well structure of InGaN/GaN.

The current spreading layer 105 is sandwiched between the n-contact layer 103 and the active layer 106. The current spreading layer 105 is composed of at least one first nitride semiconductor layer 105a made of InₓGa₍₁₋ₓ₎N, where 0<x<1, containing indium In and at least one second nitride semiconductor layer 105b made of In_{y}Ga_{(1-y)}N(0≦y<1, y<x) alternating each other. In addition, the current spreading layer 105 is composed of at least three multiple layers. Preferably, at least two of each of the first and second nitride semiconductor layers 105a and 105b alternate to form a total of at least four layers.

In addition, some successively formed nitride semiconductor layers of the current spreading layer 105 are doped with n-type dopant, and other nitride semiconductor layers are undoped. Alternatively, some successively formed nitride semiconductor layers 105a and 105b of the current spreading layer 105 may be doped with n-type dopant, and other successively formed nitride semiconductor layers 105a and 105b may be undoped. These two semiconductor layer structures may be combined as well.

If the multiple layers constituting the current spreading layer 105 are all undoped, light emission becomes uniform throughout the entire area of the device with significantly increased resistance to ESD but the operating voltage V_{f} of the light emitting device is increased. On the other hand, if the multiple layers constituting the current spreading layer 105 are all n-doped, the operating voltage decreases while uniformity of light emission and resistance to ESD are lowered.

However, as in this invention, if the doped parts (successively formed n-type nitride semiconductors) and undoped parts are suitably combined to constitute the current spreading layer 105, uniform light emission and high resistance to ESD can be obtained without increasing the operating voltage. That is, some successively formed n-doped layers in the current spreading layer suppress excessive increase of the operating voltage while the undoped layers in the current spreading layer allow uniform current application, thus achieving uniform light emission and high resistance to ESD.

In the current spreading layer 105, all of the nitride semiconductor layers 105a and 105b doped with n-type dopant may have the same doping concentration. Alternatively, some nitride semiconductor layers 105a and 105b of the current spreading layer 105 doped with n-type dopant may have the same doping concentration and other semiconductor layers 105a and 105b of the current spreading layer 105 doped with n-type dopant may have varying doping concentrations.

Preferably, each of the first nitride semiconductor layers 105a and the second nitride semiconductor layers 105b may have a thickness of up to 5 nm. With each of the first and second nitride semiconductor layers 105a and 105b having a thickness of up to 5 nm, the current spreading layer can constitute multiple layers of a superlattice structure having good crystallinity.

FIG. 2 illustrates an order of forming the layers which starts with the first nitride semiconductor layer 105a and ends with the first nitride semiconductor layers 105a, but other orders can be adopted. For example, the order can start with the first nitride semiconductor layer 105a and end with the second nitride semiconductor layer 105b, or start with the second nitride semiconductor layer 105b and end with either the first or the second nitride semiconductor layer 105a or 105b.

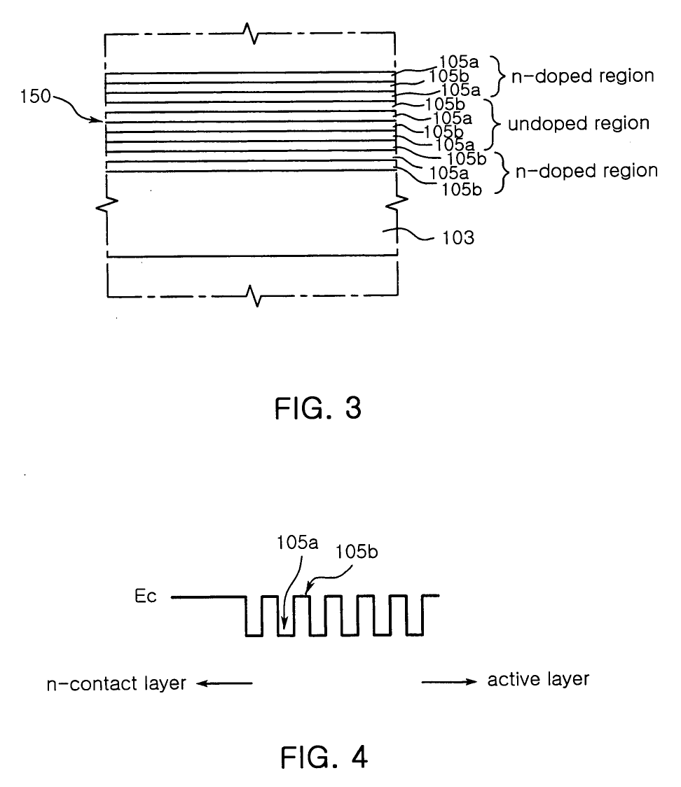

FIG. 3 is a partial sectional view illustrating the current spreading layer 105 according to an embodiment of the present invention. With reference to FIG. 3, five pairs of the first nitride semiconductor layer 105a with relatively higher In content and the second nitride semiconductor layer 105b with relatively lower In content may alternate to form a total of ten layers. For example, the first nitride semiconductor layer 105a may be made of InGaN layer and the second nitride semiconductor layer 105b can be made of GaN layer. In this case, it is preferable that the first nitride semiconductor layer 105a is made of InₓGa₍₁₋ₓ₎N, where 0.05<x<3. Since InGaN has smaller band gap than GaN, the InGaN layer (the first nitride layer) of the current spreading layer 105 forms a quantum well while the GaN layer (the second nitride semiconductor layer) of the current spreading layer 105 forms a quantum barrier in conduction band edge. The configuration of doping regions of the current spreading layer 105 and the composition of each of the nitride semiconductor layer 105 and 105b with reference to FIG. 3 are merely one illustrative embodiment, and can be variously modified within the scope of the present invention.

FIGS. 4 to 7 are diagrams illustrating conduction band edges of the current spreading layers to explain the compositions of the current spreading layers according to various embodiments of the present invention. All of the first nitride semiconductor layers 105a can have the same composition. Alternatively, the first nitride semiconductor layers 105a can have thicknesses which vary according to a distance in a thickness direction.

Referring to FIG. 4, all of the first nitride semiconductor layers 105a have the same composition. For example, in case of forming the current spreading layer 105 with multiple layers of InGaN/GaN, all of the InGaN layers (the first nitride semiconductor layers 105a) may be configured to have the same composition, thus resulting in the substantially same depth of the quantum wells in the current spreading layer.

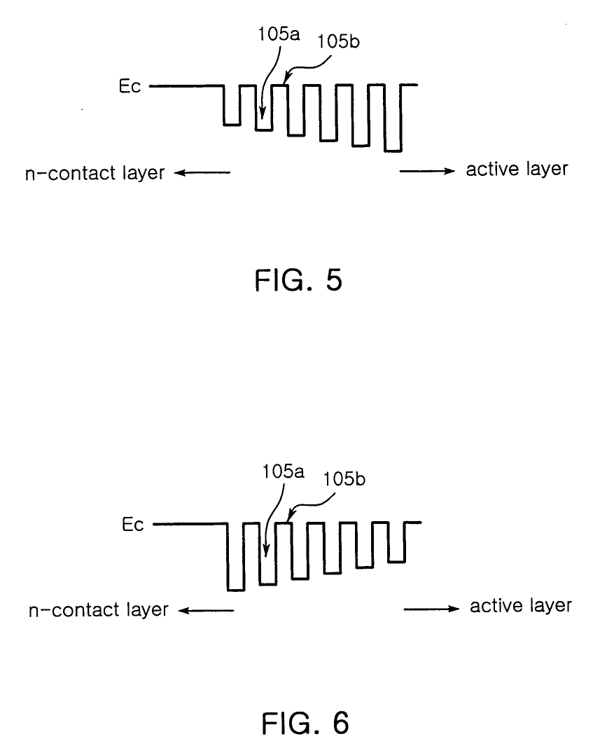

With reference to FIG. 5, the first nitride semiconductor layers 105a have compositions which vary according to a distance in a thickness direction. Particularly, the first nitride semiconductor layers 105a forming the quantum wells have In contents varying greater toward the active layer. By varying the In contents as just described, refractive indices can be varied in a thickness direction in the current spreading layer. Due to these varying refractive indices, the current spreading layer 105 can provide a light guide can be formed to adjust the mode of laser light of an LD device. In particular, if the In contents are made to vary greater (if the refractive indices are made to vary greater) toward the active layer, a superior quality light guide can be obtained while effectively adjusting the mode of laser light, thereby enhancing light output and light emission efficiency. In addition, as the In contents of the first nitride semiconductor layers 105a vary, the electrostatic capacity also varies.

Referring to FIG. 6, contrary to FIG. 5, the first nitride layers 105a have In contents varying smaller toward the active layer. By varying the In contents, the refractive indices can vary in a thickness direction in the current spreading layer, thereby forming a light guide from the current spreading layer 105 to adjust the mode of laser light of an LD device. In addition, as the In contents of the first nitride semiconductor layers 105a varies, the electrostatic capacity also varies.

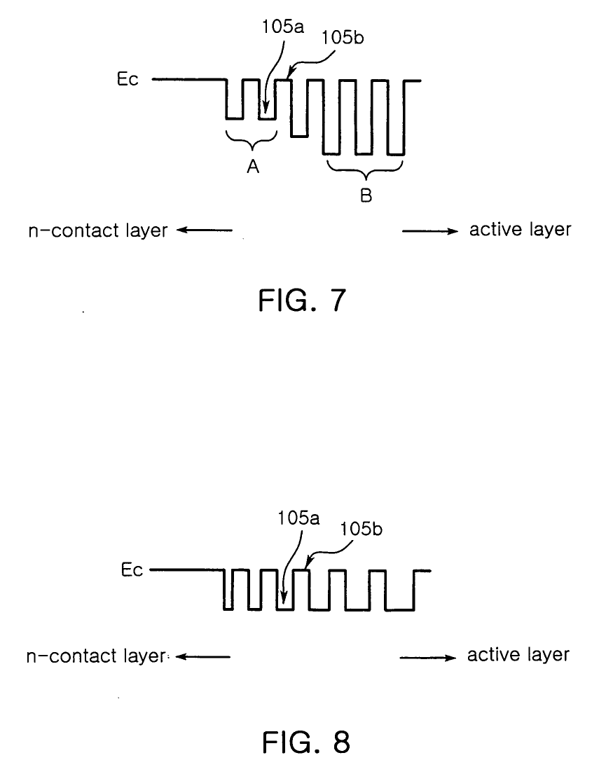

Alternatively, some first nitride semiconductor layers 105a may have the same composition while other first nitride semiconductor layers 105a can have varying compositions. Such an example is illustrated in FIG. 7. Referring to FIG. 7, two of the first nitride semiconductor layers 105a adjacent to the n-contact layer have the same In content (refer to the region denoted by ‘A’) while three of the first nitride semiconductor layers 105a adjacent to the active layer have the same In content (refer to the region denoted by ‘B’). However, the In content of the first nitride semiconductor layers 105a in the region A is different from that in the region B. Further, the first nitride semiconductor layers 105a between the region A and the region B have an In content different from the In contents of the region A and the region B. The compositions of the current spreading layer described with reference to FIGS. 4 to 7 are merely illustrative embodiments of the invention, and can be modified within the scope of the invention.

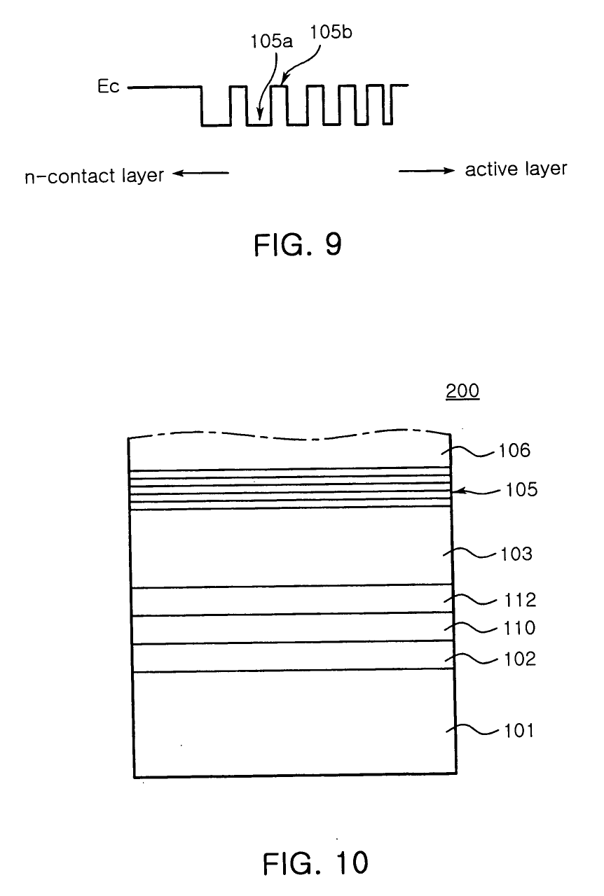

FIGS. 8 and 9 are diagrams illustrating conduction band edges of the current spreading layers to explain the change of the thicknesses of the nitride semiconductor layers constituting the current spreading layers according to certain embodiments of the invention. In the current spreading layer 105, all of the nitride semiconductor layers 105a and 105b may have the same thickness. Alternatively, the nitride semiconductor layers 105a and 105b may have varying thicknesses. Further, some nitride semiconductor layers 105a and 105b may have the same thickness while other nitride semiconductor layers 105a and 105b may have varying thicknesses.

Referring to FIG. 8, the first nitride semiconductor layers 105a have thicknesses varying greater toward the active layer. By adjusting the thickness as such, the In content can thus vary greater toward the active layer. Accordingly, the refractive indices can be increased toward the active layer. Such an adjustment of the thickness can be utilized to adjust the mode of the laser light as described hereinabove.

Referring to FIG. 9, contrary to FIG. 8, the first nitride semiconductor layers 105a have thicknesses varying smaller toward the active layer. By adjusting the thickness as such, the In contents can also vary smaller toward the active layer, and such an adjustment of the thickness can be utilized to adjust the refractive indices and the mode of laser light.

Alternatively, some first nitride semiconductor layers 105a may have the same thickness while other first nitride semiconductor layers 105a have varying thicknesses. In addition, the thicknesses of only the second nitride semiconductor layer 105b or both the first and second nitride semiconductor layers 105a and 105b can be adjusted. Moreover, the compositions as well as thicknesses of the first nitride semiconductor layer 105a can be adjusted to vary. Further, some first nitride semiconductor layers 105a may have the same compositions and thicknesses while other first nitride semiconductor layers 105a may have varying compositions and thicknesses.

FIG. 10 is a sectional view illustrating a part of a nitride semiconductor light emitting device according to another embodiment of the present invention. The semiconductor light emitting device 200 of this embodiment has the identical configuration with the aforedescribed semiconductor light emitting device 100 (see FIG. 2) except that it further includes buffer layers 110 and 112 composed of multiple layers of nitride semiconductor/SiC between the undoped GaN layer 102 and the n-contact layer 103. Therefore, the parts above the active layer 106 are omitted in the drawing. The buffer layers 110 and 112 include a SiC layer 110 formed on the undoped GaN layer 102 and an InGaN layer 112 formed on the SiC layer 110.

It is preferable that the SiC layer 110 is grown at a temperature ranging from 500 to 1500° C., and the InGaN layer 112 is grown at a low temperature range of 500 to 600° C. These buffer layers 110 and 112 allow obtainment of superior quality nitride semiconductor crystals on the buffer layers, thereby improving the light emission efficiency and resistance to ESD of the light emitting device.

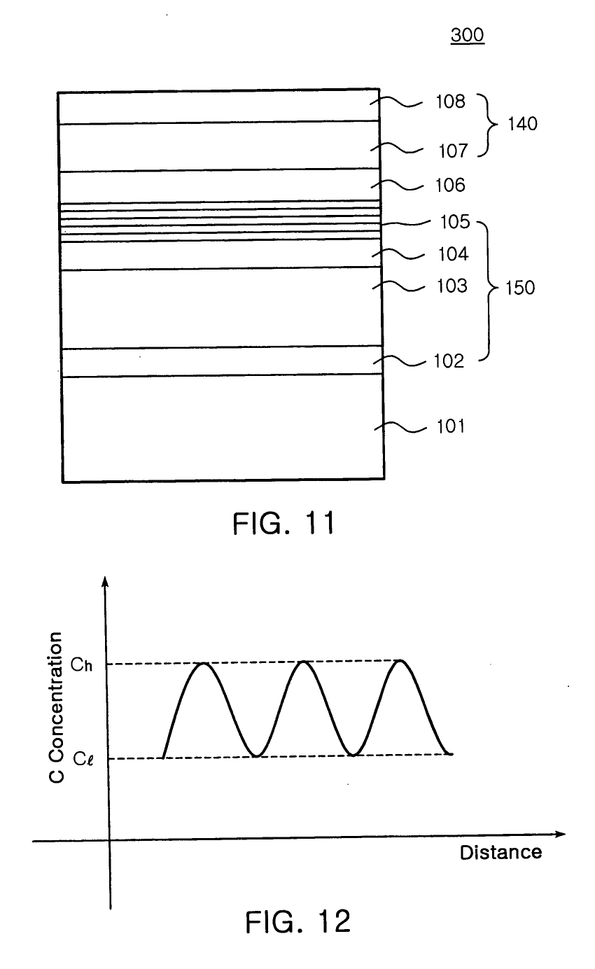

FIG. 11 is a sectional view illustrating a nitride semiconductor light emitting device according to yet another embodiment of the present invention. The nitride semiconductor light emitting device 300 of this embodiment has the identical configuration with the aforedescribed light emitting device 100 (see FIG. 2), except that it additionally includes a carbon (C) modulated doping layer 104 formed between the n-contact layer 103 and the current spreading layer 105. The C modulated doping layer 104 has a carbon doping concentration modulated according to a distance in a thickness direction. FIG. 12 illustrates the profile of the carbon concentration of the C modulated doping layer 104. As shown in FIG. 12, the C modulated doping layer 104 exhibits the carbon doping concentration which is repeatedly increased and decreased according to a distance in a thickness direction. In FIG. 12, Cₕ represents the highest level of concentration and C₁ represents the lowest level of concentration. This C modulated doping layer 104 allows further enhanced resistance to ESD.

According to the invention set forth above, current is uniformly applied due to a current spreading layer, thus allowing uniform light emission and enhanced light emission efficiency. In addition, excessive increase of operating voltage can be prevented and resistive characteristics to ESD are enhanced due to effective current injection.

While the present invention has been shown and described in connection with the preferred embodiments, it will be apparent to those skilled in the art that modifications and variations can be made without departing from the spirit and scope of the invention as defined by the appended claims.

What is claimed is:

1. A nitride semiconductor light emitting device comprising:
an n-contact layer formed on a substrate;
a current spreading layer formed on the n-contact layer;
an active layer formed on the current spreading layer; and
a p-clad layer formed on the active layer,
wherein the current spreading layer comprises at least three multiple layers composed of at least one first nitride semiconductor layer made of InₓGa₍₁₋ₓ₎N, where 0<x<1 and at least one second nitride semiconductor layer made of In_{y}Ga_{(1-y)}N, where 0≦y<1 and y<x, the first and second nitride semiconductor layers formed alternately, and
the multiple nitride semiconductor layers comprise some successive layers doped with n-type dopant and other layers which are undoped.

2. The nitride semiconductor light emitting device according to claim 1, wherein the multiple nitride semiconductor layers comprise some successive layers doped with n-type dopant and other successive layers which are undoped.

3. The nitride semiconductor light emitting device according to claim 1, wherein the some successive layers of the multiple nitride semiconductor layers doped with n-type dopant have the same doping concentration.

4. The nitride semiconductor light emitting device according to claim 1, wherein some of the nitride semiconductor layers doped with n-type dopant have the same doping concentration and other layers of the nitride semiconductor layers doped with n-type dopant have varying doping concentrations.

5. The nitride semiconductor light emitting device according to claim 1, wherein the first nitride semiconductor layer is made of InGaN and the second nitride semiconductor layer is made of GaN.

6. The nitride semiconductor light emitting device according to claim 5, wherein the first nitride semiconductor layer is made of InₓGa₍₁₋ₓ₎N, where 0.05<x<3, and the second nitride semiconductor is made of GaN.

7. The nitride semiconductor light emitting device according to claim 1, comprising a plurality of the first and nitride semiconductor layers, wherein the first nitride semiconductor layers have the same composition.

8. The nitride semiconductor light emitting device according to claim 1, comprising a plurality of the first and nitride semiconductor layers, wherein the first nitride semiconductor layers have compositions varying according to a distance in a thickness direction.

9. The nitride semiconductor light emitting device according to claim 8, wherein the first nitride semiconductor layers have In contents varying greater toward the active layer.

10. The nitride semiconductor light emitting device according to claim 8, wherein the first nitride semiconductor layers have In contents varying smaller toward the active layer.

11. The nitride semiconductor light emitting device according to claim 8, wherein some first nitride semiconductor layers have the same composition and other first nitride semiconductor layers have varying compositions.

12. The nitride semiconductor light emitting device according to claim 1, wherein the multiple layers have the same thickness.

13. The nitride semiconductor light emitting device according to claim 1, wherein the multiple layers have varying thicknesses.

14. The nitride semiconductor light emitting device according to claim 13, comprising a plurality of the first nitride semiconductor layers and a plurality of second nitride semiconductor layers, wherein the first nitride semiconductor layers or the second nitride semiconductor layers have thicknesses varying greater toward the active layer.

15. The nitride semiconductor light emitting device according to claim 13, comprising a plurality of the first nitride semiconductor layers and a plurality of second nitride semiconductor layers, wherein the first nitride semiconductor layers or the second nitride semiconductor layers have thicknesses varying smaller toward the active layer.

16. The nitride semiconductor light emitting device according to claim 13, comprising a plurality of the first and nitride semiconductor layers, wherein some of the first nitride semiconductor layers have the same thickness and some of them have varying thicknesses.

17. The nitride semiconductor light emitting device according to claim 1, wherein each of the first nitride semiconductor layer and the second nitride semiconductor layer has a thickness of up to 5 nm.

18. The nitride semiconductor light emitting device according to claim 1, comprising a plurality of the first and nitride semiconductor layers, wherein the first nitride semiconductor layers have varying compositions and thicknesses.

19. The nitride semiconductor light emitting device according to claim 1, comprising a plurality of the first and nitride semiconductor layers, wherein some first nitride semiconductor layers have the same composition and thickness and other first nitride semiconductor layers have varying compositions and thicknesses.

20. The nitride semiconductor light emitting device according to claim 1, further comprising a buffer layer having multiple layers of nitride semiconductor/SiC between the substrate and the n-contact layer.

21. The nitride semiconductor light emitting device according to claim 20, wherein the buffer layer comprises a SiC layer formed on the substrate and an InGaN layer formed on the SiC layer.

22. The nitride semiconductor light emitting device according to claim 20, further comprising an undoped GaN layer formed between the substrate and the buffer layer.

23. The nitride semiconductor light emitting device according to claim 1, further comprising a carbon modulated doped layer formed between the n-contact layer and the current spreading layer.
